(19) United States
(12) Patent Application Publication
(10) Pub. No.: US 2024/0084063 A1
(43) Pub. Date: Mar. 14, 2024

(54) SOLVENT-FREE RESIN COMPOSITION AND USES OF THE SAME

(71) Applicant: TAIWAN UNION TECHNOLOGY CORPORATION, Zhubei City (TW)

(72) Inventors: Jui-Hsiang TANG, Zhubei City (TW); Shur-Fen LIU, Zhubei City (TW)

(21) Appl. No.: 18/049,003

(22) Filed: Oct. 24, 2022

(30) Foreign Application Priority Data
Sep. 8, 2022 (TW) 111134189

(51) Int. Cl. C08F 279/02; C08F 222/06; C08K 3/22; C08K 3/36; H05K 3/00

(52) U.S. Cl. CPC C08F 279/02; C08F 222/06; C08K 3/22; C08K 3/36; H05K 3/0094; C08K 2003/2227; C08K 2201/005; C08K 2201/014

(57) ABSTRACT

A solvent-free resin composition and uses thereof are provided. The resin composition includes:
(A) a maleic acid-modified liquid hydrocarbon resin;
(B) a first filler having a D50 particle size of 1 μm to 4 μm; and
(C) a second filler having a D50 particle size of 5 μm to 10 μm.

The solvent-free resin composition can be used to fill the holes of printed circuit boards.

### CLAIM FOR PRIORITY

This application claims the benefit of Taiwan Patent Application No. 111134189 filed on Sep. 8, 2022, the subject matters of which are incorporated herein in their entirety by reference.

### BACKGROUND

### Field of the Invention

The present invention provides a solvent-free resin composition, especially a solvent-free resin composition comprising a maleic acid-modified liquid hydrocarbon resin and two fillers with specific particle sizes. The present invention also provides a printed circuit board filled with the resin composition.

### Descriptions of the Related Art

Printed circuit boards (PCBs) are substrates of electronic devices for carrying multiple electronic components that are electrically connected to provide a stable circuit working environment. Due to the development of a high-density interconnect (HDI) technique, both the width of PCBs' wirings and the interval between the wirings are decreased while the density of the wirings is increased. Conventional PCBs are now insufficient for use in the HDI circuit design. Therefore, several new types of PCBs have been developed.

In general, PCBs are formed by alternately laminating resin dielectric layers, and conductive circuit layers, wherein a plurality of holes are presented between the conductive circuit layers and the holes are plated with conductive material to form vias and thereby provide electrical connection between the conductive circuit layers. To avoid damage to the circuit in the outer layer, even out the resin dielectric layers, and meet the requirements for serving as the basis for the stacking hole structures of upper layers, the vias must be entirely filled and polished flat. A resin composition to fill the vias must have desired operation properties and electrical properties.

Conventional resin hole-filling material is based primarily on epoxy resin. For example, TW 1559471 discloses a composition for sealing and filling, which comprises a thermally curable resin, a curing agent, a flux agent and at least two inorganic fillers, wherein the inorganic fillers used in the composition comprise an inorganic filler with a mean particle size of 100 nm or less and an inorganic filler with a mean particle size from more than 150 nm to 500 nm or less. TW 201940588 discloses a thermal curable resin composition comprising an epoxy resin, a curing agent, silica, and an organic filler, wherein the thermal cure resin composition has low Dk, low coefficient of thermal expansion and good storage stability. TW 1235626 discloses a liquid thermal curable resin composition for permanently filling the holes of a printed circuit board, which comprises an epoxy resin that is liquid at room temperature, a curing catalyst, and fillers comprising spherical and ground fillers, wherein the liquid thermal curable resin composition has good thermal stability, resistance to humidity and resistance to a pressure cooker test and has a low cure shrinkage rate.

However, with the development of high-frequency and high-speed transmission and miniaturization of electronic products, conventional epoxy resin hole-filling materials can no longer meet the low dielectric constant requirement of low-loss printed circuit boards. In addition, although the coefficient of thermal expansion of conventional hole-filling materials can be reduced by adding fillers, the filling performance of conventional materials is poor. Therefore, there is an urgent need to develop a resin composition capable of solving the aforementioned problems.

### SUMMARY

Considering the aforementioned technical problems, the present invention provides a solvent-free resin composition, which utilizes a maleic acid-modified liquid hydrocarbon resin and fillers with specific particle size features. The resin composition of the present invention has excellent coating feasibility, thixotropy and printability (filling properties) and can be used for filling the holes of a printed circuit board, and the filled holes will not have deficiencies such as bubbles or resin flow. Furthermore, the dielectric material obtained by curing the resin composition has appropriate dielectric properties (i.e., low dielectric constant (Dk) and low dielectric loss factor (Df)).

Therefore, an objective of the present invention is to provide a solvent-free resin composition, which comprises:
(A) a maleic acid-modified liquid hydrocarbon resin,
(B) a first filler having a D50 particle size of 1 μm to 4 μm; and
(C) a second filler having a D50 particle size of 5 μm to 10 μm.

In some embodiments of the present invention, the filler component of the resin composition consists essentially of the first filler (B) and the second filler (C), or the filler component of the resin composition consists of the first filler (B) and the second filler (C).

In some embodiments of the present invention, the maleic acid-modified liquid hydrocarbon resin (A) is a maleic acid-modified alkadiene-based polymer. For example, the hydrocarbon resin (A) can be selected from the group consisting of maleic acid-modified liquid polybutadiene, maleic acid-modified liquid polyisoprene, maleic acid-modified liquid polycyclopentadiene, maleic acid-modified liquid polydicyclopentadiene, maleic acid-modified liquid polybutadiene-styrene copolymer, maleic acid-modified liquid styrene-isoprene copolymer, maleic acid-modified liquid styrene-butadiene-styrene copolymer, maleic acid-modified liquid styrene-butadiene-divinylbenzene copolymer, and combinations thereof.

In some embodiments of the present invention, the amount of the maleic acid-modified liquid hydrocarbon resin (A) is 20 wt % to 35 wt % based on the total weight of the resin composition.

In some embodiments of the present invention, the total amount of the first filler (B) and the second filler (C) is 40 wt % to 70 wt % based on the total weight of the resin composition.

In some embodiments of the present invention, the weight ratio of the first filler (B) to the second filler (C) is 1:2 to 1:11.

In some embodiments of the present invention, the first filler (B) and the second filler (C) are independently selected from the group consisting of silica, aluminum oxide, glass, magnesium oxide, barium sulfite, magnesium hydroxide, calcium carbonate, talc, clays, aluminum nitride, boron nitride, silicon nitride, aluminum hydroxide, silicon aluminum carbide, silicon carbide, sodium carbonate, titanium dioxide, zinc oxide, zirconium oxide, quartzes, diamonds, diamond-like carbon, graphites, calcined kaolin, pryan, micas, hydrotalcite, polytetrafluoroethylene (PTFE) powders, glass beads, ceramic whiskers, carbon nanotubes, nanosized inorganic powders, and combinations thereof.

In some embodiments of the present invention, the resin composition further comprises a cross-linking agent selected from the group consisting of diallyl phthalate, diallyl isophthalate, triallyl trimellitate, triallyl trimesate, triallyl isocyanurate (TAIC), triallyl cyanurate (TAC), prepolymers of the preceding compounds, and combinations thereof.

In some embodiments of the present invention, the resin composition further comprises an initiator selected from the group consisting of dicumyl peroxide, tert-butyl peroxybenzoate, di-tert-amyl peroxide, isopropylcumyl-tert-butyl peroxide, tert-butylcumylperoxide, di(isopropylcumyl) peroxide, di-tert-butyl peroxide, α,α′-bis(tert-butylperoxy)diisopropyl benzene, benzoyl peroxide, 1,1-bis(tert-butylperoxy)-3,3,5-trimethylcyclohexane, butyl 4,4-di(tert-butylperoxy)valerate, 2,5-dimethyl-2,5-di(tert-butylperoxy) hexane, 2,5-dimethyl-2,5-di(tert-butylperoxy)-3-hexyne, and combinations thereof.

In some embodiments of the present invention, the resin composition further comprises an additive selected from the group consisting of flame retardants, colorants, viscosity modifiers, thixotropic agents, defoaming agents, leveling agents, coupling agents, mold-release agents, surface modifying agents, plasticizers, antibacterial agents, antimould agents, stabilizers, antioxidants, phosphors, and combinations thereof.

Another objective of the present invention is to provide a printed circuit board, which has holes filled with a cured product of the aforementioned resin composition.

### BRIEF DESCRIPTION OF THE DRAWINGS

FIGS. 1A to 1C are schematic diagrams showing an embodiment of the filled printed circuit board of the present invention.

FIGS. 2A to 2C are schematic diagrams showing another embodiment of the filled printed circuit board of the present invention.

### DETAILED DESCRIPTION

Hereinafter, some embodiments of the present invention will be described in detail. However, the present invention may be embodied in various embodiments, and the protection scope of the present invention should not be limited to those described in the specification.

Unless it is additionally explained, the expressions “a,” “the,” or the like recited in the specification and in the claims should include both the singular and the plural forms.

Unless it is additionally explained, while describing the components in the solution, mixture, and composition in the specification, the weight of the solvent is not included.

Unless it is additionally explained, the expressions “first,” “second,” or the like recited in the specification and the claims are only used to distinguish the illustrated elements or components without special meanings. Those expressions are not used to represent any priority.

Unless it is additionally explained, in the specification and the claims, the term “solvent-free” means that, based on the total weight of the resin composition, the amount of the solvent is less than 5 wt %, particularly less than 3 wt %, and more particularly less than 1 wt %.

Unless it is additionally explained, in the specification and the claims, the D50 particle size is a median particle size. The D50 particle size corresponds to the particle size when the cumulative percentage reaches 50% based on volume and is measured by the dynamic light scattering method with laser light using a device for determining particle size distribution (HORIBA LB-550 DLS, produced by Horiba, Ltd.). The D90 particle size corresponds to the particle size when the cumulative percentage reaches 90% based on volume and is measured by the dynamic light scattering method with laser light using the device for determining particle size distribution.

Using a maleic acid-modified liquid hydrocarbon resin and two fillers with specific particle size features in combination in the resin composition of the present invention, the resin composition can have excellent coating feasibility, thixotropy, and printability (filling properties), and the holes filled by the resin composition do not have the defects of bubbles or resin flow. Furthermore, the dielectric material obtained by curing the resin composition can meet the dielectric properties requirements (low dielectric constant (Dk) and low dielectric loss factor (Df)) of the high-frequency and high-speed miniature electronic products. The resin composition of the present application and applications thereof are described in detail below.

### 1. RESIN COMPOSITION

The resin composition of the present invention comprises (A) a maleic acid-modified liquid hydrocarbon resin and (B) a first filler, and (C) a second filler with specific particle size features as the essential components and may further comprise optional components. The detailed descriptions of the components are as follows.

1.1. (A) Maleic Acid-Modified Liquid Hydrocarbon Resin

As used herein, “liquid hydrocarbon resin” means that the resin can flow at room temperature (such as 10° C. to 30° C.), and the other substances (especially solid substances) can be dispersed evenly in the hydrocarbon resin without using a solvent. The aforementioned hydrocarbon resin refers to a resin consisting of carbon atoms and hydrogen atoms and containing carbon-carbon double bonds. “Maleic acid-modified” means that the liquid hydrocarbon resin is graft polymerized with maleic acid and/or maleic anhydride in the polymerization chain and thus has a side chain of maleic acid and/or maleic anhydride, or that the liquid hydrocarbon resin is substituted at the end of the polymerization chain with maleic acid and/or maleic anhydride. In some embodiments of the present invention, the maleic acid-modified liquid hydrocarbon resin (A) enables even dispersion of the first filler (B), the second filler (C), and other optional components at a temperature ranging from 10° C. to 30° C. without the need of solvent, therefore enabling the provision of a solvent-free resin composition.

As used herein, the liquid hydrocarbon resin can be an aliphatic resin, an aromatic resin, or an aliphatic-aromatic copolymerized resin. In some embodiments of the present invention, the maleic acid-modified liquid hydrocarbon resin is a maleic acid-modified alkadiene-based polymer. The aforementioned alkadiene-based polymer refers to a homopolymer or a copolymer obtained by polymerizing monomer(s), which comprise alkadiene(s). Examples of the homopolymer or copolymer include a butadiene-based polymer (such as polybutadiene and butadiene-styrene copolymer), an isoprene-based polymer (such as polyisoprene and isoprene-styrene copolymer), a cyclopentadiene-based polymer, and a dicyclopentadiene-based polymer.

Examples of the maleic acid-modified liquid hydrocarbon resin include but are on limited to maleic acid-modified liquid polybutadiene, maleic acid-modified liquid polyisoprene, maleic acid-modified liquid polycyclopentadiene, maleic acid-modified liquid polydicyclopentadiene, maleic acid-modified liquid polybutadiene-styrene copolymer, maleic acid-modified liquid styrene-isoprene copolymer, maleic acid-modified liquid styrene-butadiene-styrene copolymer, and maleic acid-modified liquid styrene-butadiene-divinylbenzene copolymer. The aforementioned maleic acid-modified liquid hydrocarbon resin can be used alone or in any combination depending on need. In some embodiments of the present invention, maleic acid-modified liquid polybutadiene and maleic acid-modified liquid polybutadiene-styrene copolymer are used.

In general, based on the total weight of the resin composition, the amount of the maleic acid-modified liquid hydrocarbon resin (A) can be 20 wt % to 35 wt %. For example, based on the total weight of the resin composition, the amount of the maleic acid-modified liquid hydrocarbon resin (A) can be 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, or 35 wt %, or within a range between any two of the values described herein, but the present invention is not limited thereto.

1.2. (B) First Filler and (C) Second Filler

The filler component of the resin composition of the present invention comprises the first filler (B) and the second filler (C) or consists essentially of the first filler (B) and the second filler (C) or consists of the first filler (B) and the second filler (C). The aforementioned “filler component consists essentially of the first filler (B) and the second filler (C)” means that, based on 100 wt % of the filler component, the total amount of the first filler (B) and the second filler (C) is 90 wt % or more, more particularly 95 wt % or more.

The first filler (B) has a D50 particle size of 1 μm to 4 μm, preferably a D50 particle size of 1 μm to 3 μm. For example, the D50 particle size of the first filler can be 1 μm, 1.5 μm, 2 μm, 2.5 μm, 3 μm, 3.5 μm, or 4 μm, or within a range between any two of the values described herein. In some embodiments of the present invention, the first filler (B) further has a D90 particle size of 1 μm to 9 μm, preferably a D90 particle size of 1 μm to 5 μm. For example, the D90 particle size of the first filler (B) can be 1 μm, 1.5 μm, 2 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, or 9 μm, or within a range between any two of the values described herein.

The second filler (C) has a D50 particle size of 5 μm to 10 μm, preferably a D50 particle size of 5 μm to 9 μm. For example, the D50 particle size of the second filler (C) can be 5 μm, 5.5 μm, 6 μm, 6.5 μm, 7 μm, 7.5 μm, 8 μm, 8.5 μm, 9 μm, 9.5 μm, or 10 μm, or within a range between any two of the values described herein. In some embodiments of the present invention, the second filler (C) further has a D90 particle size of 10 μm to 30 μm, preferably a D90 particle size of 10 μm to 20 μm. For example, the D90 particle size of the second filler (C) can be 10 μm, 10.5 μm, 11 μm, 11.5 μm, 12 μm, 12.5 μm, 13 μm, 13.5 μm, 14 μm, 14.5 μm, 15 μm, 15.5 μm, 16 μm, 16.5 μm, 17 μm, 17.5 μm, 18 μm, 18.5 μm, 19 μm, 19.5 μm, 20 μm, 20.5 μm, 21 μm, 21.5 μm, 22 μm, 22.5 μm, 23 μm, 23.5 μm, 24 μm, 24.5 μm, 25 μm, 25.5 μm, 26 μm, 26.5 μm, 27 μm, 27.5 μm, 28 μm, 28.5 μm, 29 μm, 29.5 μm, or 30 μm, or within a range between any two of the values described herein.

The inventors found that when the D50 particle sizes of the first filler (B) and the second filler (C) are within the aforementioned ranges, the resin composition thus provided has good hole-filling properties (including coating feasibility, filling properties, thixotropy, etc.), and the cured product of the resin composition has appropriate dielectric properties (Dk and Df).

The materials of the first filler (B) and the second filler (C) are not particularly limited, and the material of the first filler (B) can be the same as or different from the material of the second filler (C). Examples of the first filler (B) and the second filler (C) include but are not limited to silica (such as spherical, fused, not-fused, porous, or hollow silica), aluminum oxide, glass, magnesium oxide, barium sulfite, magnesium hydroxide, calcium carbonate, talc, clays, aluminum nitride, boron nitride, silicon nitride, aluminum hydroxide, silicon aluminum carbide, silicon carbide, sodium carbonate, titanium dioxide, zinc oxide, zirconium oxide, quartzes, diamonds, diamond-like carbon, graphites, calcined kaolin, pryan, micas, hydrotalcite, polytetrafluoroethylene (PTFE) powders, glass beads, ceramic whiskers, carbon nanotubes, and nanosized inorganic powders. The aforementioned fillers can either be used alone or in any combination. In addition, the shapes of the first filler (B) and the second filler (C) are not particularly limited and may independently be crumble shape, spherical shape, needle shape, plate shape, scaly shape, hollow shape, irregular shape, hexagonal shape, three-dimensional shape, or flake shape, but the present invention is not limited thereto.

The surface of the first filler (B) and the second filler (C) can be untreated or treated with such as a silane coupling agent. Examples of the functional groups that can be introduced to the filler surface by the surface treatment include but are not limited to alkyl, vinyl, acryl, methacryl, amino, ureido, phenyl, glycidyl, anilino, isocyanurate, and styryl. Examples of the silane coupling agent suitable for the surface treatment include but are not limited to vinyltrimethoxysilane, 3-mercaptopropyltrimethoxysilane, 3-acryloxypropyltrimethoxysilane, 3-methacryloxypropyltrimethoxysilane, 3-glycidoxypropyltrimethoxysilane, 3-glycidoxypropylmethyldimethoxysilane, 3-aminopropyltrimethoxysilane, 3-(2-aminoethyl)aminopropyltrimethoxysilane, 3-(2-aminoethyl)propylmethyldimethoxysilane, 3-anilinopropyltrimethoxysilane, 3-anilinopropyltrimethoxysilane, 3-ureidopropyltrimethoxysilane, methyltrimethoxysilane, dimethyldimethoxysilane, trimethylmethoxysilane, methyltriphenoxysilane, n-propyltrimethoxysilane, n-butyltrimethoxysilane, isobutyltrimethoxysilane, n-hexyltrimethoxysilane, cyclohexyltrimethoxysilane, n-octyltrimethoxysilane, n-decyltrimethoxysilane, 1,6-bis(trimethoxysilyl)hexane, phenyltrimethoxysilane, diphenyldimethoxysilane, p-styryltrimethoxysilane, 2-(3,4-epoxycyclohexyl)ethyltrimethoxysilane, N-phenyl-3-aminopropyltrimethoxysilane, and 1,3,5-N-tris(trimethoxysilylpropyl)isocyanurate.

In general, based on the total weight of the resin composition, the total amount of the first filler (B) and the second filler (C) can be 40 wt % to 70 wt %. For example, based on the total weight of the resin composition, the total amount of the first filler (B) and the second filler (C) can be 40 wt %, 41 wt %, 42 wt %, 43 wt %, 44 wt %, 45 wt %, 46 wt %, 47 wt %, 48 wt % 49 wt %, 50 wt %, 51 wt %, 52 wt %, 53 wt % 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, or 70 wt %, or within a range between any two of the values described herein, but the present invention is not limited thereto.

In some embodiments of the present invention, the weight ratio of the first filler (B) to the second filler (C) is 1:2 to 1:11. For example, the weight ratio of the first filler (B) to the second filler (C) can be 1:2, 1:2.5; 1:3, 1:3.5, 1:4, 1:4.5, 1:5, 1:5.5, 1:6, 1:6.5, 1:7, 1:7.5, 1:8, 1:8.5, 1:9, 1:9.5, 1:10, 1:10.5, or 1:11, or within a range between any two of the values described herein. When the weight ratio of the first filler (B) to the second filler (C) is within the aforementioned range, the material obtained from the resin composition of the present invention can have better coating feasibility, filling properties, and thixotropy, and therefore better hole-filling properties.

1.3. Optional Components

In Addition to the Aforementioned Components, the Resin Composition of the Present invention may further comprise other components, such as additives known in the art, to improve the physicochemical properties of the dielectric materials obtained by curing the resin composition or to improve the processibility of the resin composition. Examples of the aforementioned additives known in the art include but are not limited to initiators, cross-linking agents, silane coupling agents, flame retardants, colorants, viscosity modifiers, thixotropic agents, defoaming agents, leveling agents, coupling agents, mold-release agents, surface modifying agents, plasticizers, antibacterial agents, antimould agents, stabilizers, antioxidants, and phosphors. The aforementioned additives can either be used alone or in any combination. Use of the additives is not described herein in detail because they are not a key feature of the present invention and can be carried out by persons having ordinary skill in the art based on the disclosure of the present invention and their ordinary skill. The following paragraphs only exemplify initiators, cross-linking agents, and silane coupling agents for illustration.

1.3.1. Initiators

Any initiator known in the art and suitable for use with maleic acid-modified liquid hydrocarbon resin can be used. Specific examples of the initiators include but are not limited to dicumyl peroxide, tert-butyl peroxybenzoate, di-tert-amyl peroxide, isopropylcumyl-tert-butyl peroxide, tert-butylcumylperoxide, di(isopropylcumyl) peroxide, di-tert-butyl peroxide, α,α′-bis(tert-butylperoxy)diisopropyl benzene, benzoyl peroxide, 1,1-bis(tert-butylperoxy)-3,3,5-trimethylcyclohexane, butyl 4,4-di(tert-butylperoxy)valerate, 2,5-dimethyl-2,5-di(tert-butylperoxy) hexane, and 2,5-dimethyl-2,5-di(tert-butylperoxy)-3-hexyne. The aforementioned peroxides can either be used alone or in any combination. In some embodiments of the present invention, 2,5-dimethyl-2,5-di(tert-butylperoxy) hexane is used.

In general, based on the total weight of the resin composition, the amount of the initiator can be 0.5 wt % to 5 wt %. For example, based on the total weight of the resin composition, the amount of the initiator can be 0.5 wt %, 1 wt %, 1.5 wt %, 2 wt %, 2.5 wt %, 3 wt %, 3.5 wt %, 4 wt %, 4.5 wt %, or 5 wt %, or within a range between any two of the values described herein, but the present invention is not limited thereto.

1.3.2. Cross-Linking Agents

Any cross-linking agents known in the art and suitable for maleic acid-modified liquid hydrocarbon resin can be used. Examples of the cross-linking agent include but are not limited to diallyl phthalate, diallyl isophthalate, triallyl trimellitate, triallyl trimesate, triallyl isocyanurate (TAIC), triallyl cyanurate (TAC), and prepolymers of the preceding compounds. The aforementioned cross-linking agents can either be used alone or in any combination. In some embodiments of the present invention, triallyl isocyanurate is used.

In general, based on the total weight of the resin composition, the amount of the cross-linking agent can be 10 wt % to 30 wt %. For example, based on the total weight of the resin composition, the amount of the cross-linking agent may be 10 wt %, 11 wt %, 12 wt %, 13 wt % 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %, or within a range between any two of the values described herein, but the present invention is not limited thereto.

1.3.3. Silane Coupling Agents

Silane coupling agents can improve the adhesion of the filler with the maleic acid-modified liquid hydrocarbon resin and can inhibit the generation of cracks in the cured product obtained from the resin composition. Specific examples of the silane coupling agent include but are not limited to alkyl silane, vinyl silane, acryl silane, methacryl silane, amino silane, ureido silane, phenyl silane, glycidyl silane, anilino silane, isocyanurate silane, and styryl silane. The aforementioned silane coupling agents can be used alone or in any combination.

In general, based on the total weight of the resin composition, the amount of the silane coupling agent can be 0.5 wt % to 5 wt %. For example, based on the total weight of the resin composition, the amount of the silane coupling agent may be 0.5 wt %, 1 wt %, 1.5 wt %, 2 wt %, 2.5 wt %, 3 wt %, 3.5 wt %, 4 wt %, 4.5 wt %, or 5 wt %, or within a range between any two of the values described herein, but the present invention is not limited thereto.

### 2. PRINTED CIRCUIT BOARD

The resin composition of the present invention can be used to fill holes (e.g., vias) in a printed circuit board. Therefore, the present invention also provides a printed circuit board that has holes filled with a cured product of the resin composition of the present invention. In general, holes in a printed circuit board can be classified as through holes and non-through holes according to whether the holes pass through the printed circuit board. Examples of through holes include but are not limited to plating through holes (PTHs) and non-plating through holes (NPTHs). Examples of non-through holes include but are not limited to buried vias, blind vias, and pits between conductive circuits. The method of forming the printed circuit board is described below with reference to the appended figures.

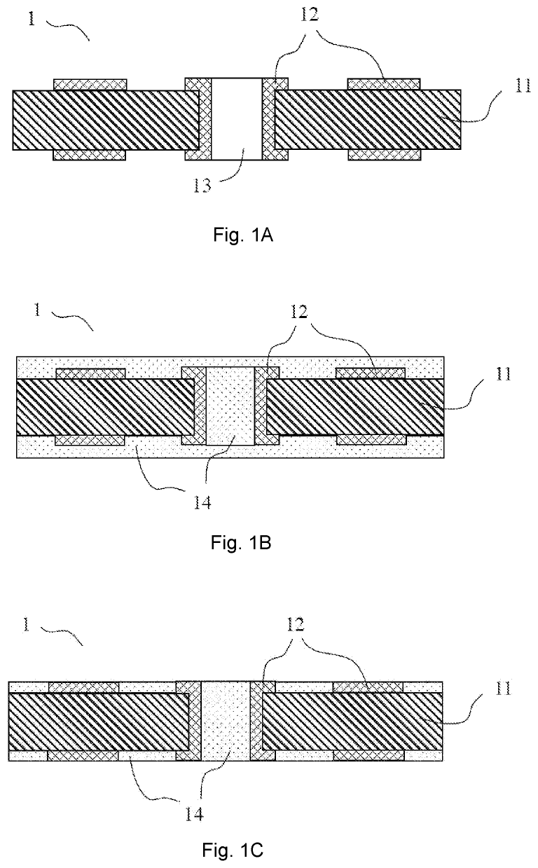

FIGS. 1A to 1C are schematic diagrams showing an embodiment of the printed circuit board of the present invention. As shown in FIG. 1A, the printed circuit board 1 has a dielectric layer 11, a conductive circuit layer 12, and a hole 13. As shown in FIG. 1B, the resin composition 14 of the present invention can be filled into hole 13 of the printed circuit board 1 using any conventional patterning method, and then the filled resin composition 14 is heated to a predetermined temperature for curing. Examples of the conventional patterning method include but are not limited to a screen-printing method, a roller coating method, a mold coating method, and a spray coating method. Finally, as shown in FIG. 1C, a cured part of the resin composition 14 that protrudes from the printed circuit board 1 is removed by grinding or polishing, thereby making the surface of the printed circuit board 1 flat to obtain the printed circuit board.

In addition, in the aforementioned grinding or polishing process, the resin composition of the present invention can be heated, for example, subjected to a thermal cure process under a temperature of 190° C. for 120 minutes, to be fully cured, and then the cured part of the resin composition that protrudes from the printed circuit board can be removed by grinding or polishing.

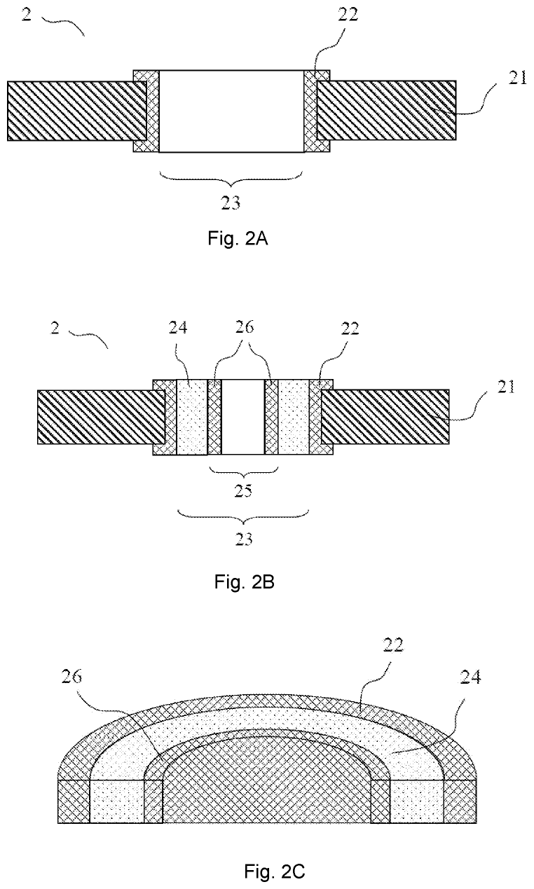

FIGS. 2A to 2C are schematic diagrams showing another embodiment of the printed circuit board of the present invention. As shown in FIG. 2A, a printed circuit board 2 has a dielectric layer 21, a conductive circuit layer 22, and a hole 23. As shown in FIG. 2B, the resin composition 24 of the present invention can be filled into hole 23 of the printed circuit board 2 by any conventional patterning method, and then the filled resin composition 24 is heated and cured. Next, a hole 25 is formed in the cured resin composition 24, wherein the hole diameter of hole 25 is smaller than that of hole 23. Afterwards, the wall of hole 25 is subjected to a metallization process to form a conductive circuit layer 26 with a smaller hole diameter. As shown in FIG. 2C, a structure in which the resin composition 24 is positioned between the conductive circuit layers 22 and 26 may be prepared in this way. Related manufacturing methods may also make reference to the Taiwan Patent TW525417, the subject matters of which are incorporated herein in their entirety by reference.

### 3. EXAMPLES

3.1. Testing Methods

The present invention will be further illustrated by the embodiments hereinafter, wherein the measuring instruments and methods are respectively as follows:

[Coating Feasibility]

The resin composition is coated onto a substrate with holes using a scraper. After that, the substrate is observed with the unaided eye. If the surface of the resin film coated on the substrate has a depression or unevenness, the result is recorded as “X”; and if there is no depression or unevenness, the result is recorded as “O”.

[Filling Properties (Printability) Test]

Glass-fiber epoxy substrates with plating through holes formed by panel plating are prepared. The thickness of each substrate is 1.6 mm, and the diameter of each plating through hole is 0.8 mm. The resin composition is filled into the plating through holes by a screen-printing method. Then, the filled glass-fiber epoxy substrates are placed in a hot-air circulating type drying furnace to conduct a thermal curing treatment at a temperature of 190° C. for 120 minutes, thereby obtaining samples. The samples are physically polished and ground. The polished and ground samples are placed under a 100× optical microscope to observe cross-sections of the filled plating through holes. The results are evaluated according to the following references. If all the plating through holes are completely filled, meaning that there is no resin flow, the result is recorded as “O”; if one or two bubbles are formed at the plating through holes, meaning that there is a little resin flow, the result is recorded as “Δ”; and if three or more bubbles are formed at the plating through holes, meaning that there is significant resin flow, the result is recorded as “X”.

[Thixotropy (TI) Test]

The prepared resin composition is tested using a digital viscometer (manufactured by BROOKFIELD, DV2T-HB) with revolutions of 6 rpm and 60 rpm, respectively, to measure the viscosities at 25° C. A viscosity ratio (viscosity at 6 rpm/viscosity at 60 rpm) is calculated from the measured viscosities. If the value ranges from 2 to 3, then the thixotropy of the resin composition is evaluated as excellent.

[Dielectric Constant (Dk) and Dielectric Loss Factor (Df) Measurement]

The shiny side of copper foil coated with the resin composition is then placed in a hot-air circulating type drying furnace to conduct a thermal curing treatment under a temperature of 190° C. for 120 minutes. After that, the resin composition is removed from the shiny side of the copper foil. The dielectric constant and the dielectric loss factor of the resin composition are measured according to IPC-TM-650 2.5.5.13 standard under an operating frequency of 10 GHz.

3.2. List of Raw Materials Used in Examples and Comparative Examples

| Model | |
|---|---|
| number | Description |
| MV | Maleic acid-modified liquid hydrocarbon resin, available from |
| MA60 | Evonik. |
| 184MA6 | Maleic acid-modified liquid hydrocarbon resin, available from |
| | Ricon. |
| EPMAT | Acrylic acid-modified liquid hydrocarbon resin, available |
| | from Evonik. |
| L5F | Polytetrafluoroethylene (PTFE) powder filler (D50 = 4 μm, |
| | D90 = 5 μm), available from Daikin Industries. |
| EQH1010- | SiO₂ filler (D50 = 1 μm, D90 = 1.5 μm), available from |
| SSk | Applichem Technology Corp. |
| SXD6500 | SiO₂ filler (D50 = 2.5 μm, D90 = 4.5 μm), available from |
| | Toyota Tsusho (Taiwan) Co., Ltd. |
| Al₂O₃ | Aluminum oxide filler (D50 = 9 μm, D90 = 20 μm), available |
| | from Showa Denko. |
| EQ5010- | SiO₂ filler (D50 = 5 μm, D90 = 10 μm), available from |
| SMC | Applichem Technology Corp. |
| SS-0090 | SiO₂ filler (D50 = 9 μm, D90 = 18.7 μm), available from |
| | Sibelco. |
| SS-0105- | SiO₂ filler (D50 = 0.8 μm, D90 = less than 5 μm), available |
| R14 | from Sibelco. |
| VF09020- | SiO₂ filler (D50 = 4.5 μm, D90 = 9.6 μm), available from |
| SB | Applichem Technology Corp. |
| VF- | SiO₂ filler (D50 = 25 μm, D90 = 41.47 μm), available from |
| 25045- | Applichem Technology Corp. |
| SLB | |
| Luperox | Initiator, available from Symtake Chemical Co., Ltd. |
| 101 | |
| TAIC | Cross-linking agent, available from Evonik. |
| KS66 | Defoaming agent, available from Topco Technologies Corp. |
| Nsilane | Silane coupling agent, available from Evonik. |
| TiO₂ | Titanium dioxide, available from Prior Company Ltd. |

3.3. Preparation of the Resin Composition

According to the components and proportions shown in Table 1 and Table 2, the components were mixed using a stirrer at room temperature, then kneaded and dispersed in a three-roll mill machine to obtain the resin compositions of Examples E1 to E8 and Comparative Examples CE1 to CE9.

TABLE 1

| Unit: parts by weight | | | E1 | E2 | E3 | E4 | E5 | E6 | E7 | E8 |
|---|---|---|---|---|---|---|---|---|---|---|
| Resin | MV MA60 | | 80 | 80 | 80 | | 80 | 80 | 80 | 80 |
| | 184MA6 | | | | | 80 | | | | |
| | EPMAT | | | | | | | | | |
| Filler | First | L5F | | | | | | 20 | 10 | |
| components | filler | EQH1010-SSK | 60 | 60 | | | | | 50 | 15 |
| | | SXD6500 | | | 60 | 60 | 60 | | | |
| | Second | Al₂O₃ | | | | | | 70 | 60 | |
| | filler | EQ5010-SMC | 120 | | | | | | 60 | 165 |
| | | SS-0090 | | 120 | 120 | 120 | 120 | | | |
| Initiator | Luperox 101 | | 5.2 | 5.2 | 5.2 | 5.2 | 5.2 | 5.2 | 5.2 | 5.2 |
| Cross-linking | TAIC | | 40 | 40 | 40 | 40 | 40 | 40 | 40 | 40 |
| agent | | | | | | | | | | |
| Defoaming | KS66 | | 3 | 3 | 3 | 3 | 3 | 3 | 3 | 3 |
| agent | | | | | | | | | | |
| Silane coupling | Nsilane | | 3 | 3 | 3 | 3 | 3 | 3 | 3 | 3 |
| agent | | | | | | | | | | |

| | | | | | | | | |
|---|---|---|---|---|---|---|---|---|
| TiO₂ | 12 | 12 | 12 | 12 | 0 | 12 | 12 | 12 |
| Weight ratio | 1:2 | 1:2 | 1:2 | 1:2 | 1:2 | 2:7 | 1:2 | 1:11 |
| (First filler:second filler) | | | | | | | | |

TABLE 2

| Unit: parts by weight | | | CE1 | CE2 | CE3 | CE4 | CE5 | CE6 | CE7 | CE8 | CE9 |
|---|---|---|---|---|---|---|---|---|---|---|---|
| Resin | MV MA60 | | 80 | 80 | 80 | 80 | 80 | 80 | | 80 | 80 |
| | 184MA6 | | | | | | | | | | |
| | EPMAT | | | | | | | | 80 | | |
| Filler | First | L5F | | | | | | | | | 60 |
| components | filler | EQH1010- | | | | | 60 | | 60 | 60 | |
| | | SSK | | | | | | | | | |
| | | SXD6500 | 60 | 120 | | 180 | | | | 60 | 120 |
| | Second | Al₂O₃ | | | | | | | | | |
| | filler | EQ5010- | | | | | | | 120 | | |
| | | SMC | | | | | | | | | |
| | | SS-0090 | | | | | | 120 | | | |

| | | | | | | | | | | |
|---|---|---|---|---|---|---|---|---|---|---|
| | SS-0105-R14 | | 60 | | | | | | | |
| | VF09020-SB | | | | | 120 | 60 | | | |
| | VF-25045-SLB | 120 | | 180 | | | | | | |
| Initiator | Luperox 101 | 5.2 | 5.2 | 5.2 | 5.2 | 5.2 | 5.2 | 5.2 | 5.2 | 5.2 |
| Cross-linking | TAIC | 40 | 40 | 40 | 40 | 40 | 40 | 40 | 40 | 40 |
| agent | | | | | | | | | | |
| Defoaming | KS66 | 3 | 3 | 3 | 3 | 3 | 3 | 3 | 3 | 3 |
| agent | | | | | | | | | | |
| Silane coupling | Nsilane | 3 | 3 | 3 | 3 | 3 | 3 | 3 | 3 | 3 |
| agent | | | | | | | | | | |

| | | | | | | | | | |
|---|---|---|---|---|---|---|---|---|---|
| TiO₂ | 12 | 12 | 12 | 12 | 12 | 12 | 12 | 12 | 12 |
| Weight ratio | — | — | — | — | — | — | 1:2 | — | — |
| (First filler:second filler) | | | | | | | | | |

3.4. Test of the Resin Composition

The properties of the resin compositions of the Examples and the Comparative Examples, including coating feasibility, filling properties, thixotropy (TI), dielectric constant (Dk), and dielectric loss factor (Df), were tested according to the aforementioned testing methods, and the results are tabulated in Table 3 and Table 4.

TABLE 3

| | | E1 | E2 | E3 | E4 | E5 | E6 | E7 | E8 |
|---|---|---|---|---|---|---|---|---|---|
| Hole-filling | Coating feasibility | ◯ | ◯ | ◯ | ◯ | ◯ | ◯ | ◯ | ◯ |
| properties | Filling properties | ◯ | ◯ | ◯ | ◯ | ◯ | ◯ | ◯ | ◯ |
| | Thixotropy (TI) | 2.38 | 2.36 | 2.55 | 2.64 | 2.32 | 2.65 | 2.10 | 2.09 |
| Dielectric | Dk@10 GHz | 2.727 | 3.414 | 3.139 | 3.109 | 2.786 | 3.413 | 3.333 | 3.057 |
| properties | (RC: 55%) | | | | | | | | |
| | Df@10 GHz | 0.00568 | 0.00611 | 0.00582 | 0.00567 | 0.00544 | 0.00966 | 0.00752 | 0.00484 |
| | (RC: 55%) | | | | | | | | |

*RC refers to resin content.

TABLE 4

| | | CE1 | CE2 | CE3 | CE4 | CE5 | CE6 | CE7 | CE8 | CE9 |
|---|---|---|---|---|---|---|---|---|---|---|
| Hole-filling | Coating feasibility | ◯ | X | ◯ | ◯ | ◯ | X | X | ◯ | X |
| properties | Filling properties | X | X | X | X | Δ | X | X | X | X |
| | Thixotropy (TI) | 1.21 | 4.54 | 1.64 | 1.01 | 3.1 | 3.71 | 5.34 | 1.02 | 10.12 |
| Dielectric | Dk@10 GHz | 3.226 | 3.367 | 3.017 | 3.140 | 3.266 | 3.231 | 3.187 | 3.167 | 2.560 |
| properties | (RC: 55%) | | | | | | | | | |
| | Df@10 GHz | 0.00595 | 0.00640 | 0.00588 | 0.00490 | 0.00525 | 0.00538 | 0.00599 | 0.00496 | 0.00502 |
| | (RC: 55%) | | | | | | | | | |

*RC refers to resin content.

As shown in Table 3 and Table 4, the solvent-free resin compositions of the present invention have good thixotropy and excellent filling properties (printability), the filled holes would not have defects such as bubbles or resin flow. The dielectric materials obtained by curing the resin compositions have appropriate dielectric Dk and Df. By contrast, Comparative Example CE3 shows that when the first and second fillers are not used in the resin composition, the resin composition has poor filling properties and thixotropy (TI). CE4, CE8, and CE9 show that when only the first filler is used in the resin composition, the resin composition has poor filling properties and thixotropy. Comparative Examples CE1, CE2, CE5, and CE6 show that when the resin composition does not comprise both the first filler and the second filler, the resin composition materials cannot simultaneously have good coating feasibility, filling properties and thixotropy. Comparative Example CE7 shows that, when the maleic acid-modified liquid hydrocarbon resin is not used in the resin composition, the resin composition has poor coating feasibility, filling properties, and thixotropy.

The above examples are used to illustrate the principle and efficacy of the present invention and show the inventive features thereof. People skilled in this field may proceed with a variety of modifications and replacements based on the disclosures and suggestions of the invention as described without departing from the principle thereof. Therefore, the scope of protection of the present invention is as defined in the claims as appended.

### BRIEF DESCRIPTION OF REFERENCE NUMERALS

1, 2: printed circuit board
11, 21: dielectric layer
12, 22, 26: conductive circuit layer
13, 23, 25: holes
14, 24: resin composition

What is claimed is:

1. A solvent-free resin composition, which comprises:
(A) a maleic acid-modified liquid hydrocarbon resin;
(B) a first filler having a D50 particle size of 1 μm to 4 μm; and
(C) a second filler having a D50 particle size of 5 μm to 10 μm.

2. The resin composition of claim 1, wherein the maleic acid-modified liquid hydrocarbon resin (A) is a maleic acid-modified alkadiene-based polymer.

3. The resin composition of claim 2, wherein the maleic acid-modified liquid hydrocarbon resin (A) is selected from the group consisting of maleic acid-modified liquid polybutadiene, maleic acid-modified liquid polyisoprene, maleic acid-modified liquid polycyclopentadiene, maleic acid-modified liquid polydicyclopentadiene, maleic acid-modified liquid polybutadiene-styrene copolymer, maleic acid-modified liquid styrene-isoprene copolymer, maleic acid-modified liquid styrene-butadiene-styrene copolymer, maleic acid-modified liquid styrene-butadiene-divinylbenzene copolymer, and combinations thereof.

4. The resin composition of claim 1, wherein the amount of the maleic acid-modified liquid hydrocarbon resin (A) is 20 wt % to 35 wt % based on the total weight of the resin composition.

5. The resin composition of claim 1, wherein the total amount of the first filler (B) and the second filler (C) is 40 wt % to 70 wt % based on the total weight of the resin composition.

6. The resin composition of claim 1, wherein the weight ratio of the first filler (B) to the second filler (C) is 1:2 to 1:11.

7. The resin composition of claim 1, wherein the first filler (B) and the second filler (C) are independently selected from the group consisting of silica, aluminum oxide, glass, magnesium oxide, barium sulfite, magnesium hydroxide, calcium carbonate, talc, clays, aluminum nitride, boron nitride, silicon nitride, aluminum hydroxide, silicon aluminum carbide, silicon carbide, sodium carbonate, titanium dioxide, zinc oxide, zirconium oxide, quartzes, diamonds, diamond-like carbon, graphites, calcined kaolin, pryan, micas, hydrotalcite, polytetrafluoroethylene (PTFE) powders, glass beads, ceramic whiskers, carbon nanotubes, nanosized inorganic powders, and combinations thereof.

8. The resin composition of claim 1, further comprising a cross-linking agent selected from the group consisting of diallyl phthalate, diallyl isophthalate, triallyl trimellitate, triallyl trimesate, triallyl isocyanurate (TAIC), triallyl cyanurate (TAC), prepolymers of the preceding compounds, and combinations thereof.

9. The resin composition of claim 1, further comprising an initiator selected from the group consisting of dicumyl peroxide, tert-butyl peroxybenzoate, di-tert-amyl peroxide, isopropylcumyl-tert-butyl peroxide, tert-butylcumylperoxide, di(isopropylcumyl) peroxide, di-tert-butyl peroxide, α,α′-bis(tert-butylperoxy)diisopropyl benzene, benzoyl peroxide, 1,1-bis(tert-butylperoxy)-3,3,5-trimethylcyclohexane, butyl 4,4-di(tert-butylperoxy)valerate, 2,5-dimethyl-2,5-di(tert-butylperoxy) hexane, 2,5-dimethyl-2,5-di(tert-butylperoxy)-3-hexyne, and combinations thereof.

10. The resin composition of claim 1, further comprising an additive selected from the group consisting of flame retardants, colorants, viscosity modifiers, thixotropic agents, defoaming agents, leveling agents, coupling agents, mold-release agents, surface modifying agents, plasticizers, antibacterial agents, antimould agents, stabilizers, antioxidants, phosphors, and combinations thereof.

11. A printed circuit board, which has holes filled with a cured product of the resin composition of claim 1.
